(19) United States
(12) Patent Application Publication
(10) Pub. No.: US 2013/0135237 A1
(43) Pub. Date: May 30, 2013

(54) ELECTRONIC APPARATUS WITH DUAL DISPLAY SCREENS

(71) Applicant: Synergy Optoelectronics (Shenzhen) Co., Ltd., Shenzhen (CN)

(72) Inventors: Hai-Long Li, Shenzhen (CN); Chien-Chung Fang, Hsinchu (TW)

(73) Assignee: Synergy Optoelectronics (Shenzhen) Co., Ltd., Shenzhen (CN)

(21) Appl. No.: 13/688,234

(22) Filed: Nov. 29, 2012

(30) Foreign Application Priority Data
Nov. 29, 2011 (CN) 201110387176.3

(51) Int. Cl. G06F 3/14; G03F 5/00

(52) U.S. Cl. CPC G06F 3/1423; G03F 5/00
USPC 345/173; 359/893

(57) ABSTRACT

An electronic apparatus includes a display body, a first input body, and the second input body. The display body includes two opposite surfaces and first and the second display screens located at the two opposite surfaces respectively. The first input body is pivotally engaged with the display body, and the first input body includes a first input surface corresponding to the first display screen. The second input body is pivotally engaged with the display body, and the second input body includes a second input surface corresponding to the second two display screen.

### BACKGROUND

1. Technical Field

The present disclosure relates to an electronic apparatus with dual display screens.

2. Description of Related Art

Laptop computers are popular due to their lightweight nature and smaller size compared with a desktop computer. A typical laptop computer includes an input body and a display device. The display device includes a display screen, and is pivotally engaged with the input body via a pivot axle, such that the display device can be positioned at a desired angle relative to the input body.

When the laptop computer is in use, a user needs to be in front of the display screen, otherwise the user cannot view images displayed on the display screen. However, in some circumstances (such as in a meeting), the laptop computer may be used to display information to multiple users, where the laptop computer cannot provide images for users who are in back of the display screen. This brings inconvenience for the users.

What is needed is to provide a means that can overcome the above-described limitations.

### BRIEF DESCRIPTION OF THE DRAWINGS

The components in the drawings are not necessarily drawn to scale, the emphasis instead placed upon clearly illustrating the principles of at least one embodiment. In the drawings, like reference numerals designate corresponding parts throughout the various views, and all the views are schematic.

FIG. 1 is an isometric view of an electronic apparatus according to an embodiment of the present disclosure, the electronic apparatus being in a standby state.

FIG. 2 is an isometric view of the electronic apparatus of FIG. 1 when the electronic apparatus is in a first operation state.

FIG. 3 is an isometric view of the electronic apparatus of FIG. 1 when the electronic apparatus is in a second operation state.

FIG. 4 is an isometric view of the electronic apparatus of FIG. 1 when the electronic apparatus is in a third operation state.

FIG. 5 is an isometric view of the electronic apparatus of FIG. 1 when the electronic apparatus is in a fourth operation state.

FIG. 6 is a block diagram of a control circuit of the electronic apparatus of FIG. 1.

### DETAILED DESCRIPTION

Reference will be made to the drawings to describe certain exemplary embodiments of the present disclosure.

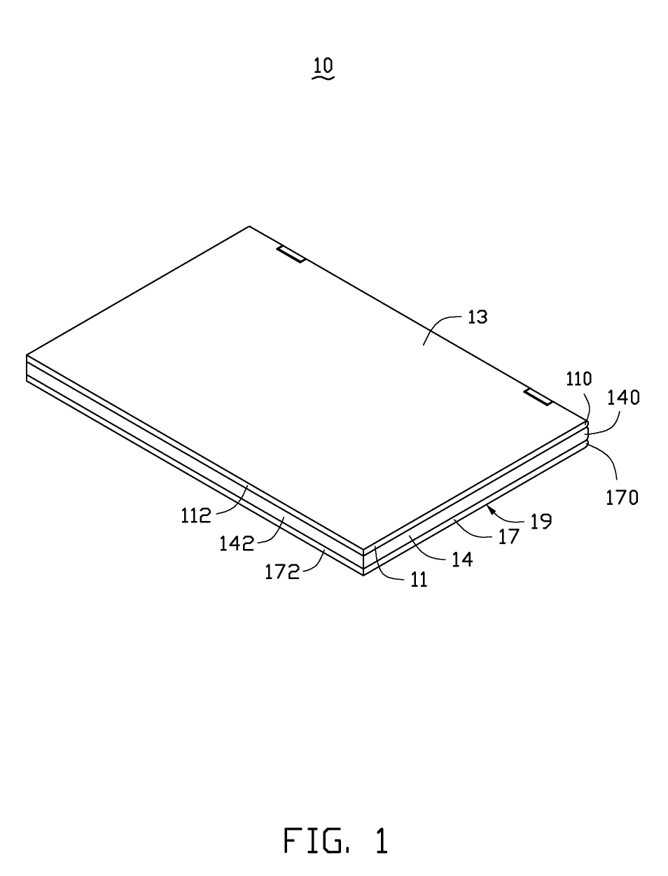

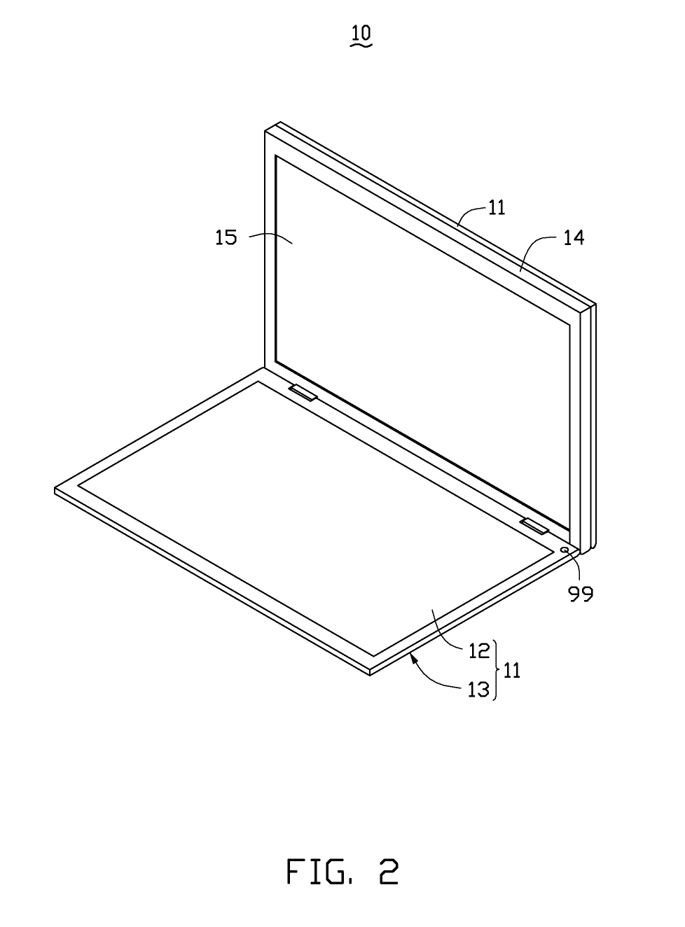

Referring to FIGS. 1-5, an electronic apparatus 10 according to an embodiment of the present disclosure is shown. The electronic apparatus 10 may be a laptop computer, and includes a first input body 11, a display body 14, and a second input body 17. The first input body 11, the second input body 17, and the display body 14 are all in rectangular in shape. The first input body 11 and the second input body 17 are pivotally engaged with the display body 14, such that each of the first input body 11 and the second input body 17 can be rotated at a desired angle relative to the display body 14. When the electronic apparatus 10 is in a standby state, the first input body 11 and the second input body 17 may be folded up towards the display body 14, such that the first input body 11, the second input body 17 and the display body are in close proximity to one another, and the display body 14 is sandwiched between the first input body 11 and the second input body 17, as shown in FIG. 1. When the electronic apparatus 10 is in an operation state, at least one of the first input body 11 and the second input body 17 is rotated at a desired angle relative to the display body 14, so that the display body 14 is exposed to provide images for a user, as shown in FIG. 2-5.

The display body 14 includes a first display screen 15 and a second display screen 16. The first display screen 15 and the second display screen 16 are located on two opposite main surfaces of the display body 14 respectively. The first input body 11 includes a first input interface 12 and a first bottom surface 13. The first input interface 12 faces and corresponds to the first display screen 15, and is opposite to the first bottom surface 13. The second input body 17 includes a second input interface 18 and a second bottom surface 19. The second input interface 18 faces and corresponds to the second display screen 15, and is opposite to the second bottom surface 19. In one embodiment, each of the first display screen 15 and the second display screen 16 are a touch display screen, and each of the first input surface 12 and the second input surface 13 are a touch surface of a touch input display screen.

Moreover, the first input body 11 further includes a first engagement end 110 that is engaged with the display body 14, and a first distal end 112 far away from the first engagement end 112. The second input body 17 further includes a second engagement end 170 that is engaged with the display device 14 and a second distal end 172 far away from the second engagement end 170. The display body 14 further includes a third engagement end 140 and a third distal end 142 far away from the third engagement end 140. The first engagement end 110 and the second engagement end 170 are pivotally engaged with the third engagement end 140, that is, the first input body 11 and the second input body 17 are engaged with the display body 14 at a same engagement end (the third engagement end 140).

Referring to FIG. 2, when the electronic apparatus 10 is in the first operation state, the second input body 17 and the display body 14 are folded up together, and the first input body 11 is rotated at a first desired angle (such as 90 degrees) relative to the display body 14 and the second input body 17. The first display screen 15 displays images for a user, and the user can operate the first input interface 12 to control the images of the first display screen 15. Moreover, in the first operation state, the electronic apparatus 10 is support by the first input body 11. In detail, the first input body 11 can be positioned on a support object (such as a table) with the first bottom surface 12 contacting the support object, so as to support the electronic apparatus 10 on the support object.

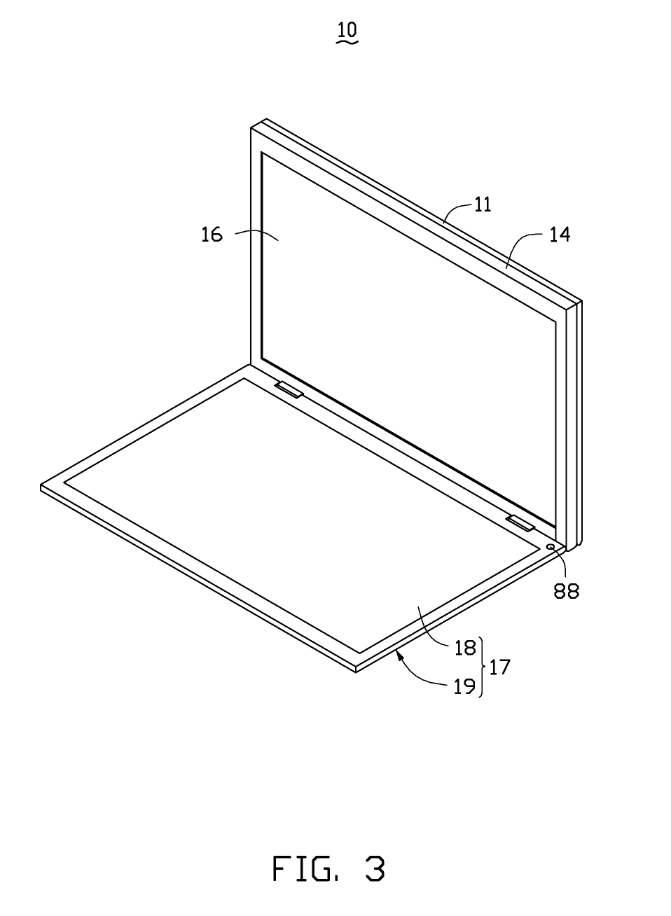

Referring to FIG. 3, when the electronic apparatus 10 is in the second operation state, the first input body 11 and the display body 14 are folded up together, and the second input body 17 is rotated at a second desired angle (such as 90 degrees) relative to the display body 14 and the first input body 11. The second display screen 16 displays images for the user, and the user can operate the second input interface 18 of the second input body 17 to control the images of the second display screen 16. Moreover, the electronic apparatus 10 is support by the second input body 17, that is, the second input body 17 can be positioned on a support object with the second bottom surface 19 contacting the support object, so as to support the electronic apparatus 10 on the support object.

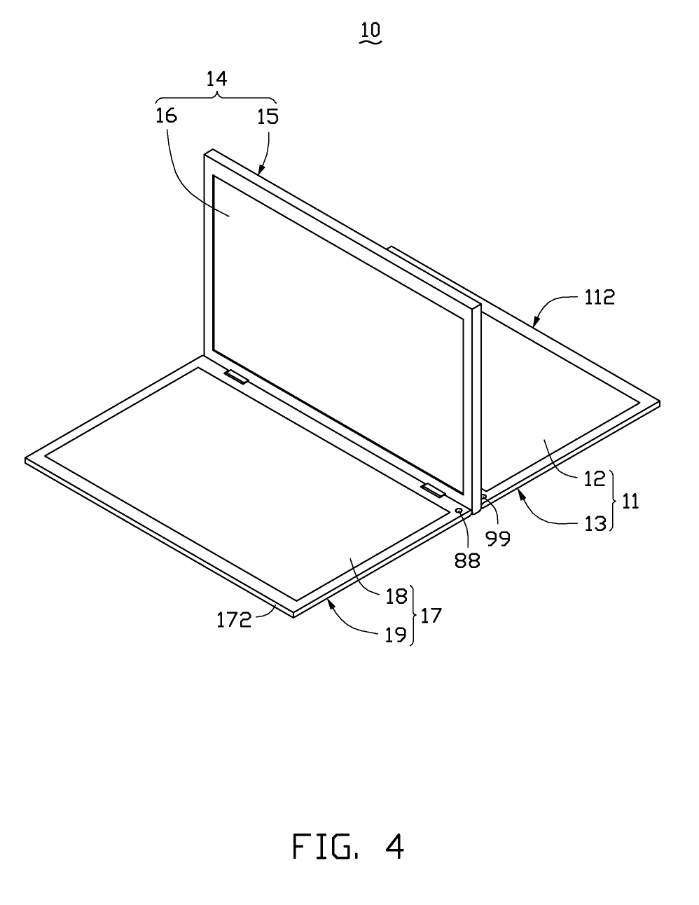

Referring to FIG. 4, when the electronic apparatus 10 is in the third operation state, the first input body 11 and the second input body 17 are rotated at a third desired angle (such as 90 degrees) relative to the display body 14, respectively. The first and the second display screens 15 and 16 display images for at least two users in two opposites sides of the electronic apparatus 10, and each of the at least two users can operate an adjacent input surface 12 or 18 of the input body (the first input body 11 or the second input body 17) to control the images of the adjacent display screen 15 or 16. Moreover, the electronic apparatus 10 is supported by the first and the second input bodies 11 and 17, that is, the first and the second input bodies 11 and 17 can be positioned on a support object with the first and the second bottom surfaces 13 and 19 contacting the support object, so as to support the electronic apparatus 10 on the support object.

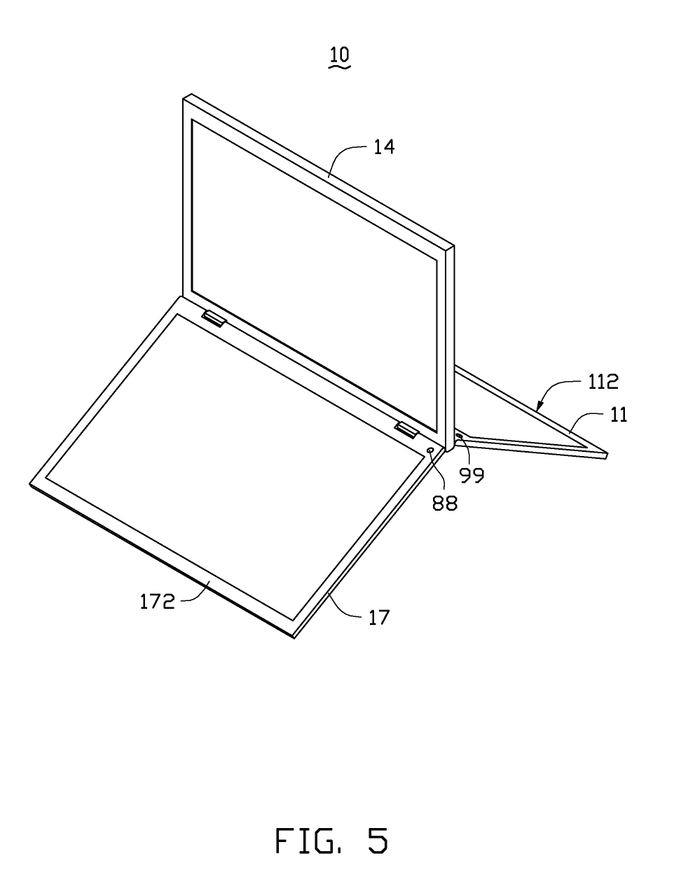

Referring to FIG. 5, when the electronic apparatus 10 is in the fourth operation state, the first input body 11 and the second input body 17 are rotated at a fourth desired angle which is greater than 90 degrees and less than 180 degrees) relative to the display body 14. The first and the second display screens 15 and 16 display images for the users in two opposites sides of the electronic apparatus 10, and each of the users can operate an adjacent input surface 12 or 18 of the input body (the first input body 11 or the second input body 17) to control the images of the second display screen 16. Moreover, the electronic apparatus 10 is support by the first and the second input bodies 11 and 17, that is, the first and the second input bodies 11 and 17 can be positioned on a support object with the first and the second distal ends 112 and 172 contacting the support object, so as to support the electronic apparatus 10 on the support object.

Furthermore, when the electronic apparatus 10 is in the third operation state or the fourth operation state, the first display screen 15 and the second display screen 16 can display same image simultaneously, and the images of the first display screen 15 and the second display screen 16 can be selectively controlled by the one of the first input surface 12 and the second input surface 18 based on the user operation. In the embodiment, the first input body 11 further includes a first button 99, and the second input body 17 further includes a second button 88. The users can operate the first button 99 and the second button 88 to select one of the first input body 11 and the second input body 17 to control the images of the two display screens 15 and 16.

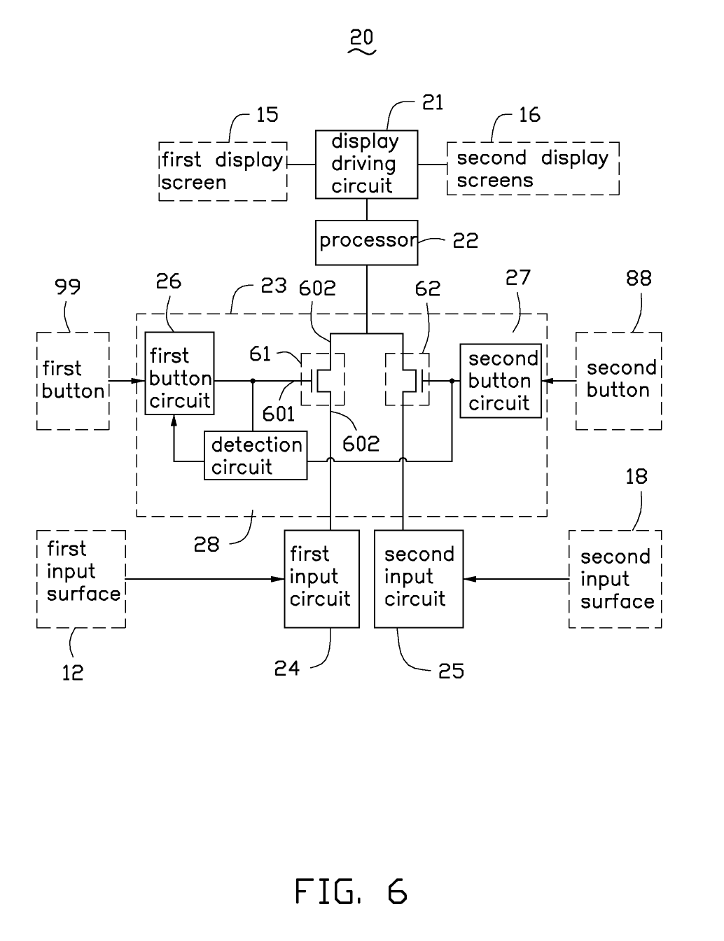

It can be understood that the electronic apparatus 10 should include a control circuit 20 configured to control the images of the two display screens 15 and 16 according to the operations of the users provided on the first input surface 12 and the second input surface 18. In the embodiment, when the electronic apparatus is in an operation state (such as the third or the fourth operation state) and each of the first input body 11 and the second input body 17 is rotated at a desired angle relative to the display body 14, the two display screens 15 and 16 display same images all the time. Referring to FIG. 6, the control circuit 20 of the electronic apparatus 10 of FIG. 1 is shown. The control circuit 20 includes a display driving circuit 21, a processor 22, a first input circuit 24, a second input circuit 25, and a switching circuit 23. The first input surface 12 is electrically connected to the first input circuit 24 and is configured to control the first input circuit 24 to output a first input control signal based on the operation (of the user) provided on the first input surface 12. The second input surface 18 is electrically connected to the second input circuit 25 and is configured to control the second input circuit 25 to output a second input control signal based on the operation (of the user) provided on the second input surface 18. The switching circuit 23 is configured to receive the first input control signal and the second input control signal and selectively provide the first input control signal or the second input control signal based on the operation provided on the two buttons 99 and 88. The processor 22 is configured to receive the first input control signal or the second input control signal from the switching circuit 23 and control the display driving circuit 21 to output driving signals to drive the two display screens 15 and 16.

The switching circuit 23 includes a first button circuit 26, a second button circuit 27, a first switch element 61, a second switch element 62, and a detection circuit 28. The first switch element 61 is connected between the first input circuit 24 and the processor 22, and the second switch element 62 is connected between the second input circuit 25 and the processor 22. The first button 99 is electrically connected to the first button circuit 99 and is configured to control the first button circuit 26 to output a first switch control signal to switch on or switch off the first switch element 61. The second button 88 is electrically connected to the second button circuit 27 and is configured to control the second button circuit 27 to output a second switch control signal to switch on or switch off the second switch element 62. The detection circuit 28 is configured to detect the first switch control signal and the second switch control signal and control the first button circuit 26 to switch off the first switch element 61 when the two switch elements 61 and 62 are switched on.

The first switch element 61 and the second switch element 62 are a switch transistor which includes two connection terminals 602 (e.g., drain, source terminals) and a control terminal 601 (e.g., gate terminal). The control terminal 601 of the first switch element 61 is connected to the first button circuit 26 to receive the first switch control signal. The two connection terminals 602 of the first switch element 61 are connected to the first input circuit 24 and the processor 22 respectively and configured to transmit the first input control signal to the processor 22 when the first switch element 61 is switched on. The control terminal 601 of the second switch element 61 is connected to the second button circuit 27 to receive the second switch control signal. The two connection terminals 602 of the second switch element 62 are connected to the second input circuit 25 and the processor 22 respectively and configured to transmit the second input control signal to the processor 22 when the second switch element 62 is switched on.

When a user presses the first button 99, the first button 99 provides a trigger signal to the first button circuit 26, the first button circuit 26 outputs the first switch control signal which is a high level signal (logic 1) to the first switch element 61 to switch on the first switch element 61, such that the first input circuit 24 can provide the first input control signal to the processor 22 via the first switch element 61, and the images of the two display screens 15 and 16 are controlled by the first input surface 12. Further, when the user presses the first button 99 again, the first button 99 provides a trigger signal to the first button circuit 26 again, the first button circuit 26 outputs the first switch control signal which is a low level signal (logic 0) to the first switch element 61 to switch off the first switch element 61, such that the first input circuit 24 cannot provide the first input control signal to the processor 22.

When a user presses the second button 88, the second button 88 provides a trigger signal to the second button circuit 27, the second button circuit 27 outputs the second switch control signal which a is high level signal to the second switch element 62 to switch on the second switch element 62, such that the second input circuit 27 can provide the second input control signal to the processor 22 via the second switch element 62, and the images of the two display screens 15 and 16 are controlled by the second input surface 18. Furthermore, when the user presses the second button 88 again, the second button 88 provides a trigger signal to the second button circuit 27 again, the button circuit 27 outputs the second switch control signal which is a low level signal to the second switch element 62 to switch off the second switch element 88, such that the second input circuit 25 cannot provide the second input control signal to the processor 22.

When the first button circuit 26 and the second button circuit 27 output the first and the second switch control signals to switch on the first and the second switch elements 61 and 62 based on the user operations, the detection circuit 28 detects the first and the second switch control signals and controls the first button circuit 26 to switch off the first switch element 61, such that the first input circuit 24 can provide the second input control signal to the processor 22. Accordingly, the images of the two display screens 15 and 16 are controlled by the second input surface 18.

In summary, the display body 14 of the electronic apparatus has two display screens, the two display screens 15 and 16 can provide images for multiple users located at two opposite sides of the electronic apparatus 10. Thus, the electronic apparatus 10 brings convenience to the users. Moreover, due to the two buttons 99 and 88 and the switching circuit 23, the users can select one of the first input surface 12 and the second input surface 18 to control images of the two display screens 15 and 16, it also brings convenience to the users.

It is to be further understood that even though numerous characteristics and advantages of preferred and exemplary embodiments have been set out in the foregoing description, together with details of the structures and functions of the embodiments, the disclosure is illustrative only; and that changes may be made in detail, especially in the matters of shape, size and arrangement of parts within the principles of the present disclosure to the full extent indicated by the broad general meaning of the terms in which the appended claims are expressed.

What is claimed is:

1. An electronic apparatus, comprising:
a display body comprising two opposite surfaces, a first display screen, and a second display screen; the first display screen and the second display screen located at the two opposite surfaces respectively; and
a first input body pivotally engaged with the display body, the first input body comprising a first input surface corresponding to the first display screen; and
a second input body pivotally engaged with the display body, the second input body comprising a second input surface corresponding to the second display screen.

2. The electronic apparatus of claim 1, wherein the display body comprises an engagement end, the first input body and the second input body are pivotally engaged with the engagement end.

3. The electronic apparatus of claim 1, wherein the first input body comprises a first engagement end pivotally engaged with the display body and a first distal end far away from the first engagement end, the second input body comprises a second engagement end pivotally engaged with the display body and a second distal end far away from the second engagement end, the first distal end and the second distal end are configured to support the electronic apparatus when each of the first input body and the second input body are rotated at a desired angle that is greater than 90 degrees and less than 180 degrees.

4. The electronic apparatus of claim 1, wherein when the electronic apparatus is in an operation state and each of the first input body and the second input body is rotated at a desired angle relative to the display body, the first and the second display screens displaying same images.

5. The electronic apparatus of claim 1, wherein when the electronic apparatus is in a standby state, the first input body and the second input body are folded up towards the display body, such that the display body is sandwiched between the first input body and the second input body.

6. The electronic apparatus of claim 1, wherein each of the first input surface and the second input surface are a touch surface of a touch input display screen.

7. The electronic apparatus of claim 1, wherein the electronic apparatus comprises a control circuit electrically connected between the first and the second input surfaces and the first and the second display screens, the control circuit comprises a first input circuit, a second input circuit, a switching circuit, a processor, and a display driving circuit, the first input surface is electrically connected to the first input circuit and is configured to control the first input circuit to output a first input control signal based on an operation provided on the first input surface, the second input surface is electrically connected to the second input circuit and is configured to control the second input circuit to output a second input control signal based on an operation provided on the second input surface, the switching circuit is configured to receive the first input control signal and the second input control signal and selectively provide the first input control signal or the second input control signal to the processor, and the processor is configured to receive the first input control signal or the second input control signal and control the display driving circuit to output driving signals to drive the first and second display screens.

8. The electronic apparatus of claim 7, wherein the first input body further comprises a first button, the second input body further includes a second button, and the first button and the second button are electrically connected to the switching circuit and configured to control the switching circuit provide the first input control signal or the second input control signal to the processor.

9. The electronic apparatus of claim 8, wherein the switching circuit comprises a first button circuit, a second button circuit, a first switch element, a second switch element, and a detection circuit, the first switch element is connected between the first input circuit and the processor, the second switch element is connected between the second input circuit and the processor, the first button is electrically connected to the first button circuit and is configured to control the first button circuit to output a first switch control signal to switch on or switch off the first switch element, the second button is electrically connected to the second button circuit and is configured to control the second button circuit to output a second switch control signal to switch on or switch off the second switch element, the detection circuit is configured to detect the first switch control signal and the second switch control signal and control the first button circuit to switch off the first switch element when the two switch elements are switched on.

10. The electronic apparatus of claim 9, wherein the first switch element and the second switch element are a switch transistor comprising two connection terminals and a control terminal, the control terminal of the first switch element is connected to the first button circuit to receive the first switch control signal, the two connection terminals of the first switch are connected to the first input circuit and the processor respectively and configured to transmit the first input control signal to the processor when the first switch element is switched on, the control terminal of the second switch element is connected to the second button circuit to receive the second switch control signal, and the two connection terminals of the second switch are connected to the second input circuit and the processor respectively and configured to transmit the second input control signal to the processor when the second switch element is switched on.

11. An electronic apparatus, comprising:
a display body comprising a first display screen, a second display screen, and an engagement end located at one side of the first and the second display screens; the first display screen and the second display screen located at two opposite surfaces of the display body respectively;
a first input body pivotally engaged with the engagement end, the first input body comprising a first input surface configured to control images of the first display screen; and
a second input body pivotally engaged with the engagement end, the second input body comprising a second input surface configured to control images of the second display screen.

12. The electronic apparatus of claim 11, wherein the first input body comprises a first engagement end pivotally engaged with the display body and a first distal end far away from the first engagement end, the second input body comprises a second engagement end pivotally engaged with the display body and a second distal end far away from the second engagement end, the first distal end and the second distal end are configured to support the electronic apparatus when each of the first input body and the second input body are rotated at a desired angle that is greater than 90 degrees and less than 180 degrees.

13. The electronic apparatus of claim 11, wherein when the electronic apparatus is in an operation state and each of the first input body and the second input body is rotated at a desired angle relative to the display body, the first and the second display screens displaying same images.

14. The electronic apparatus of claim 11, wherein when the electronic apparatus is in a standby state, the first input body and the second input body are folded up towards the display body, such that the display body is sandwiched between the first input body and the second input body.

15. The electronic apparatus of claim 11, wherein each of the first input surface and the second input surface are a touch surface of a touch input display screen.

16. The electronic apparatus of claim 11, wherein the electronic apparatus comprises a control circuit electrically connected between the first and the second input surfaces and the first and the second display screens, the control circuit comprises a first input circuit, a second input circuit, a switching circuit, a processor, and a display driving circuit, the first input surface is electrically connected to the first input circuit and is configured to control the first input circuit to output a first input control signal based on an operation provided on the first input surface, the second input surface is electrically connected to the second input circuit and is configured to control the second input circuit to output a second input control signal based on an operation provided on the second input surface, the switching circuit is configured to receive the first input control signal and the second input control signal and selectively provide the first input control signal or the second input control signal to the processor, and the processor is configured to receive the first input control signal or the second input control signal and control the display driving circuit to output driving signals to drive the first and the second display screens.

17. The electronic apparatus of claim 16, wherein the first input body further comprises a first button, the second input body further includes a second button, and the first button and the second button are electrically connected to the switching circuit and configured to control the switching circuit provide the first input control signal or the second input control signal to the processor.

18. The electronic apparatus of claim 17, wherein the switching circuit comprises a first button circuit, a second button circuit, a first switch element, a second switch element, and a detection circuit, the first switch element is connected between the first input circuit and the processor, the second switch element is connected between the second input circuit and the processor, the first button is electrically connected to the first button circuit and is configured to control the first button circuit to output a first switch control signal to switch on or switch off the first switch element, the second button is electrically connected to the second button circuit and is configured to control the second button circuit to output a second switch control signal to switch on or switch off the second switch element, the detection circuit is configured to detect the first switch control signal and the second switch control signal and control the first button circuit to switch off the first switch element when the two switch elements are switched on.

19. The electronic apparatus of claim 18, wherein the first switch element and the second switch element are a switch transistor comprising two connection terminal and a control terminal, the control terminal of the first switch element is connected to the first button circuit to receive the first switch control signal, the two connection terminals of the first switch are connected to the first input circuit and the processor respectively and configured to transmit the first input control signal to the processor when the first switch element is switched on, the control terminal of the second switch element is connected to the second button circuit to receive the second switch control signal, and the two connection terminals of the second switch are connected to the second input circuit and the processor respectively and configured to transmit the second input control signal to the processor when the second switch element is switched on.
